(19) United States
(12) Patent Application Publication
(10) Pub. No.: US 2024/0353257 A1
(43) Pub. Date: Oct. 24, 2024

(54) SWITCH MODULE BASED ON PROXIMITY ACTIVATION BY MEANS OF AN INFRARED REFLECTIVE SENSOR

(71) Applicants: Beatriz Surroca Ferreri, Alicante (ES); Farola Tech S.A.S., Montevideo (UY)

(72) Inventors: Neri Javier MENDEZ CARDOZO, Montevideo (UY); Luis Mathias MAIDANA DE LEON, Montevideo (UY)

(73) Assignees: Beatriz Surroca Ferreri, Alicante (ES); Farola Tech S.A.S., Montevideo (UY)

(21) Appl. No.: 18/687,604

(22) PCT Filed: Sep. 1, 2021
(86) PCT No.: PCT/ES2021/070632

§ 371 Date: Feb. 28, 2024

(51) Int. Cl. G01J 1/44; G01J 1/02; G01J 1/04

(52) U.S. Cl. CPC G01J 1/44; G01J 1/0488; G01J 2001/0276

(57) ABSTRACT

A proximity switch module activated by an infrared reflective sensor that is triggered solely by IR light emitted by the module itself, turning on and off when a body is brought within activation distance, receiving the electrical network charge gradually, capable of being embedded into spaces intended for mechanical switches, allowing for positioning of three or more modules in line that operate independently. The switch module is based on an electronic board that includes an infrared reflective sensor, a capacitive power supply, a 100V to 250V optocoupler-activated thyristor, terminals blocks, a thermal safety fuse, capacitors, a status indicator light, a zero-crossing chip, a casing, a casing cover, and a piece that allows only IR light from the module to pass through.

### CROSS REFERENCE TO RELATED APPLICATION

This application is a national stage entry of PCT/ES2021/070632 filed Sep. 1, 2021, under the International Convention.

### FIELD OF THE INVENTION

The invention is related to the field of proximity switches, and, in particular, to a proximity activation switch module using an infrared reflective sensor (IR) coded to be activated only by the light of the spectrum of the IR module itself, so it can be used both, indoors or outdoors, and, beneficially it turns on and off with any volume or mass that comes close to the activation distance, receiving the electrical network charge gradually, protecting light fixtures, home appliances, thus avoiding possible problems caused by voltage spikes. The switch module of the invention presents a suitable size for being embedded in compartments intended for mechanical switches, and allows three or more switch modules to be positioned in line that operate independently.

### BACKGROUND OF THE INVENTION

Various types of switches are known in the state of the art, such as tactile switches, and switches with heat-activated infrared sensors.

Switches with heat-activated infrared sensors are not part of the background of the invention hereby presented, for this kind of switches use heat as a working parameter, which makes their working outdoors erratic because of their exposure to solar radiation.

These switches are designed to work with direct current (DC) provided by a transformer outside the switch.

Regarding the known tactile switches, electronic technicians know that, when power outages occur in the electrical networks, the electrical tactile switches turn off or reset, and when the power is back, the electronic tactile switches return to the initial power off position, even when the power outage is brief.

Likewise, it is known by electronic technicians that moisture and corrosive agents affect electrical tactile switches, which limits them as far as its uses, they cannot be used in humid environments or outdoors, nor in environments with corrosive agents.

On the other hand, electrical tactile switches do not contribute to the lifespan of light fixtures and appliances, given the fact that they deliver the full charge of the electrical network. The known electrical tactile switches are affected by voltage spikes when turning on light fixtures and appliances.

Therefore, technical problems associated with infrared heat-activated sensors and tactile switches are summarized in:
infrared heat-activated sensors cannot be exposed to solar radiation due to possible erratic activations, that is to say that they turn on or off by themselves, and therefore they cannot be used outdoors.

Electrical tactile switches turn off or reset when a power outage occurs, returning to the initial power off position.

Electrical tactile switches cannot be exposed to moisture or corrosive agents due to possible circuit damage.

Electrical tactile switches do not contribute to the lifespan of light fixtures and appliances, given the fact that they deliver the full charge of the electrical network and do not protect light fixtures and appliances from voltage spikes when turning on.

Thereby there is no known background to the invention provided here.

### SUMMARY OF THE INVENTION

The present invention allows to solve the issues previously exposed, providing a switch module for proximity activation using an infrared sensor that consists of:
An electronic board that includes the following components:
an infrared reflective sensor composed by an infrared transmitter that emits a coded light signal which bounces in objects, and an infrared receptor that captures the coded light signal and measures the distance between the module and the volume or mass that interacts with itself for the purpose of turning it on or off.
a capacitive power supply unit that is fed by reactive power from the electrical network, which can support two different voltages;
a 100V to 250V optocoupler-activated thyristor that drives the electrical load;
two terminal blocks, an electrical load input terminal block, and an electrical load output terminal block. In the context of the present invention “terminal block” should be understood as a set of individual or multiple terminals and its respective accessories. By definition, terminals or electrical connection terminals, are contacts used to divert electrical energy produced by a power source to the consuming device;
a security thermal fuse;
a group of capacitors;
a status indicator light
a zero-crossing chip. The zero-crossing chip allows the switch module, when turning on, to receive an order to send a graduated charge in three hundredths of a second instead of 220 V or 110 V. That is from 0% to 100%, gradually, contributing to the lifespan of light fixtures and appliances. Due to this gradual transition, voltage spikes that occur in conventional switches at the moment of turning on lights and appliances are eliminated, thus protecting them and prolonging their lifespan.
a memory.

Preferable, the electronic board and its components present an anti-moisture and anti-corrosion coating as they undergo treatment with products intended to protect these pieces. Thereby the proximity activation switch module using an infrared reflective sensor of the invention operates in humid environments and those exposed to corrosive agents, thanks to the moisture and corrosion-resistant treatment.

A casing, preferably made of plastic material, in which the electronic board with its components is placed. It consists of a hollow rectangular prism open in one of its faces. The upper face of the casing consists of two openings from the inside to the outside. The object of these openings is to facilitate upper access to the terminal blocks. Also, each one of the lateral faces of the casing has an opening from the inside to the outside of the surface to expose one of the terminal blocks. Additionally, each of the lateral faces of the casing is provided with a slot inside of similar length, and parallel to the lower edge of each lateral face; and female-type cavities close to the lateral edges of the open face of the rectangular prism. The lateral openings of the casing must be at the same height of the terminal blocks, in order to leave them exposed and thus be able to install the wiring that will allow the connection of the power supply and the load.

A casing covering, that consists of one opening form the inside to the outside on its surface; which is linked by its edges to the open face of the prism that forms the casing, preferably using an adhesive; and
A piece of material capable of allowing only the light of the IR spectrum of the switch module to pass through, and that has the size that matches the size of the opening in the casing covering, in such a way that the piece is linked by its borders to the mentioned opening of the casing covering.

The components of the electronic board are placed over both faces of it, preferably attached by welding. Most components are attached by welding to the upper face, while a minority of them are also attached by welding to the lower face. Once the components are welded, they and the electronic board are subjected to a moisture and corrosion-resistant treatment The electronic board has a rectangular shape and consists of a perimeter space where no components are welded to it. In this way, the edges of the electronic board, free of components, are inserted and secured by pressure into the slots located inside of the lateral faces of the casing.

Also, in a preferred embodiment of the invention, the casing and its covering are attached with an adhesive glue. Likewise, the plastic material that allows only the light of the IR spectrum of the switch module to pass through, is attached in the opening of the casing covering by an adhesive glue.

According to a preferred embodiment of the invention, the switch module is complemented with a back cover with male-type protrusions that serves to insert the switch module into the wall enclosure or on the surface where the module is planned to be installed.

The male-type protrusions of the back cover are inserted in the female-type cavities of the casing, before embedding the switch module into the wall enclosure or on the surface where it is intended to be installed. This way, the cover of the casing with the piece of material that allows only the light of the IR spectrum to pass through, crosses the opening of the back cover. Once the switch module is embedded in the wall, a plate or trim with an opening is optionally placed on the back cover, through which the covering casing with the piece of material that allows the light of the IR spectrum to pass through is inserted. The plate is then fitted to the wall by conventional means.

The proximity activation switch module through an infrared reflective sensor connects with the wiring before being embedded in the wall and operates without the need for adjustment. Likewise, before embedding the switch module, the charge input terminal block and the charge output terminal block are connected with the wiring. One of the terminal blocks is for connecting power wiring, and the other terminal block is for connecting load wiring, namely: lighting and other appliances.

Once installed and embedded in the wall, the switch module activates when a body approaches within the reach of activation distance, approximately 7 cm (2.75 in), which triggers both its on and off functions.

On the other hand, the switch module of the invention features a memory that allows the maintenance of the initial output state. This implies that the switch module does not turn off or reset when power outages occur and, when power is reestablished, the switches return to the initial power off position, even when the power outage is brief. In this sense, the invention provides complete immunity to interference from the electrical network, so that, if power outages occur, the invention maintains the same state to that of the time of the outage.

The proximity activation switch module through an infrared reflective sensor operates within a voltage range of 100 V and 250 V of the electric network.

The switch module can be manufactured for single installation or manufactured for installation in groups of three or more in line, with the advantage that each of them operates independently from the others.

Regarding the operation of the proximity activation switch module through an infrared reflective sensor, it is worth noting that it does not use heat as an operating parameter, instead, it is exclusively activated by light in the IR spectrum emitted by itself. Therefore, it can be used both indoors and outdoors since, for example, solar radiation does not affect it. In this sense, the invention provides complete light immunity.

The proximity activation switch module, through an infrared reflective sensor, is placed in a wall outlet without the need to modify the standard frames of mechanical switches. It is compatible with the same compartment as mechanical switches and therefore interchangeable. The module can be manufactured for single installation or manufactured for installation in groups of three or more in line, with the advantage that each of them operates independently from the others.

The configuration described above for the switch module of the invention provides a device that advantageously measures the distance to an object that stands in front of it by bouncing an infrared signal, without requiring the temperature of the hand as a reference parameter for the measurement. Additionally, the advocated switch module offers a switch that mimics the performance of known mechanical switches and does not turn off in the event of a power outage, as is the case with tactile switches.

Finally, it is worth highlighting that the proximity activation switch module through an infrared reflective sensor of the invention does not use a transformer, unlike the direct current switches, and employs a capacitive power source. This allows for a compact-sized switch module to be offered.

### BRIEF DESCRIPTION OF DRAWINGS

To complement the description that will be provided below and in order to aid in better understanding the features of the invention, according to a preferred example of its practical implementation, a set of drawings is included as an integral part of this description. These drawings, provided for illustrative purposes and not limiting, represent the following:

FIG. 1.—Shows a side view of the electronic board, the upper part of which shows: the emitter of the infrared reflective sensor, a status indicator light, a group of capacitors, a zero-crossing chip, a security thermal fuse, a capacitive energy power source, an optocoupler-activated thyristor, and an input terminal block, In accordance with a preferred realization of the invention.

FIG. 2.—Shows a top view of the electronic board where the emitter and receiver of the infrared reflective sensor can be seen, a status indicator light, a group of capacitors, a zero-crossing chip, a security thermal fuse, a capacitive energy power source, an optocoupler-activated thyristor, and an input terminal block, and an output terminal block.

FIG. 3.—Shows a side view depicting the disassembly of the following components of the electronic board according to the preferred realization, illustrated in the previous figures: the emitter of the infrared reflective sensor, a status indicator light, the receiver of the infrared reflective sensor, a group of capacitors, a zero-crossing chip, a security thermal fuse, a capacitive energy power source, an optocoupler-activated thyristor, an input terminal block, and an output terminal block.

FIG. 4.—Shows a side view depicting the disassembly of the proximity activation switch module through an infrared reflective sensor, where the following can be seen: the electronic board with components arranged on its top, the casing, a slot, a side opening intended to expose one of the terminal blocks, a female-type cavity, casing cover, a piece of plastic material suitable for allowing only IR spectrum light from the module to pass through. Additionally, a plate and a back cover with a male-type protrusion can be observed.

FIG. 5.—Shows a top view of the proximity activation switch module through an infrared reflective sensor where the following can be seen: terminal blocks, casing cover, casing. Additionally, a plate and a back cover with male-type protrusions can be observed.

FIG. 6.—Shows a side view of the proximity activation switch module through an infrared reflective sensor, where the following can be seen: the output charge terminal block, the casing, a side opening in the casing exposing the output charge terminal, and the casing cover. Additionally, a plate and a back cover with a male-type protrusion can be observed.

FIG. 7.—Shows a rear view of the board and the back cover with the male-type protrusions.

FIG. 8.—Shows a front view of the board. The casing cover, the emitter and receiver of the infrared reflective sensor, a status indicator light, and the piece of plastic material suitable for allowing only IR spectrum light from the switch module to pass through.

FIG. 9.—Shows a front perspective view of the board with an opening, where the opening is intended to allow the casing cover and the casing of the proximity activation switch module through an infrared reflective sensor to pass through.

FIG. 10.—Shows a perspective view of the casing where one of its side openings, the two openings on the top face, the two female-type cavities on the side faces, and one of the two slots can be observed.

FIG. 11.—Shows a side view with one of the two female-type cavities and one of the two side openings.

FIG. 12.—Shows a top view of the casing with its two openings on the top face.

FIG. 13.—Shows a perspective disassembled view of the casing, the casing cover, and the piece of material suitable for allowing only IR spectrum light to pass through.

FIG. 14.—Shows an assembled perspective of the casing, the cover, and the piece of material suitable for allowing only IR spectrum light to pass through.

FIG. 15.—Shows a lateral disassembled view of the casing with one of the side openings, with one of the two female-type cavities on one of its side faces; a lateral disassembled view of the casing cover; and a lateral disassembled view of the plastic piece suitable for allowing only IR spectrum light from the switch module to pass through.

FIG. 16.—Shows a lateral view of the elements represented in FIG. 15 assembled.

FIG. 17.—Shows a top disassembled view of the casing with its two upper openings; a top disassembled view of the casing cover; and a top disassembled view of the plastic piece suitable for allowing only IR spectrum light from the switch module to pass through.

FIG. 18.—Shows a top view of the elements represented in FIG. 17 assembled.

FIG. 19.—Shows an assembled lateral view of the casing with one of the side openings, with one of the two female-type cavities on one of its side faces; a lateral view of the casing cover assembled to the casing; and a lateral disassembled view of the back cover and one of the two male-type protrusions.

FIG. 20.—Shows an assembled lateral view of the casing with one of the side openings; a lateral view of the casing cover assembled to the casing; and an assembled lateral view of the back cover and one of the two male-type protrusions.

FIG. 21.—Shows an assembled top view of the casing with its two upper openings; a top view of the casing cover assembled to the casing; and a top disassembled view of the back cover with two male-type protrusions.

FIG. 22.—Shows an assembled top view of the casing with its two upper openings; a top view of the casing cover assembled to the casing; and a top view of the back cover with two male-type protrusions assembled to the casing.

FIG. 23.—Shows an assembled perspective view of the casing with one of its side openings, with its two openings on the top face, with one of the two female-type cavities on one of its side faces; with the casing cover assembled to the casing, which includes an opening from inside to outside on its surface, in which a piece of plastic material suitable for allowing only IR spectrum light from the switch module to pass through is attached; and a perspective disassembled view of the back cover with an opening and some male-type protrusions.

FIG. 24.—Shows an assembled perspective view of the casing with one of its side openings, with its two openings on the top face; with the casing cover assembled to the casing, which includes an opening from inside to outside on its surface, in which a piece of plastic material suitable for allowing only IR spectrum light from the switch module to pass through is attached; and a perspective view of the back cover with an opening and one of the two male-type protrusions assembled to the casing.

### PREFERRED EMBODIMENT OF THE INVENTION

The following describes a preferred embodiment of proximity activation switch module through an infrared reflective sensor, without implying a limitation regarding other forms of implementing the invention.

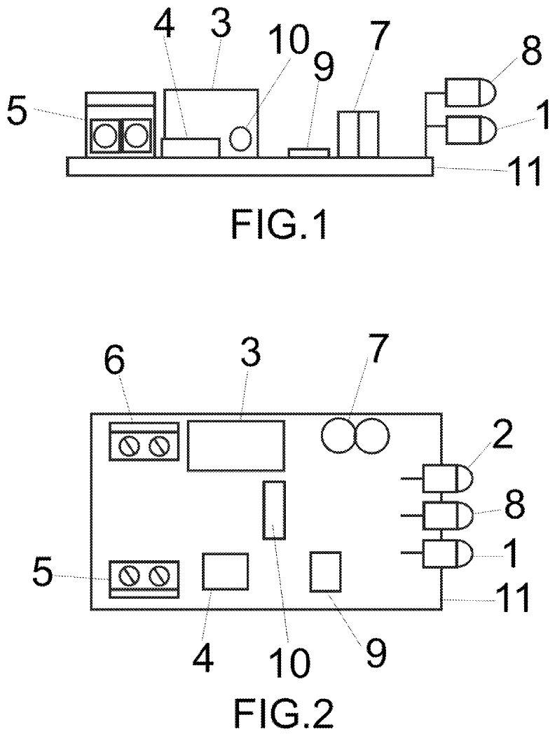

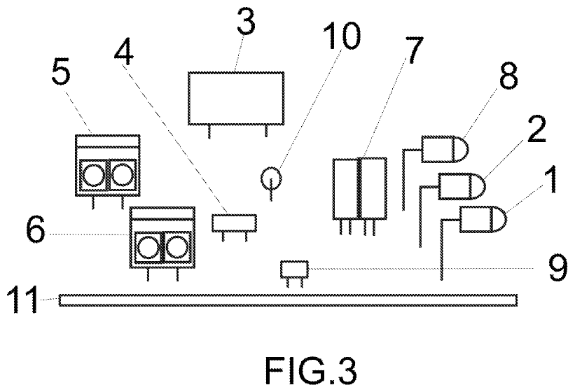

Firstly, as seen in FIGS. 1 to 4, components welded onto an electronic board (11) are arranged. These components include: an infrared reflective sensor that includes an infrared emitter (1) and an infrared receiver (2) that receives the encoded signal and measures the distance between the module and the volume or mass interacting with it for the purpose of turning it on or off; a capacitive power source (3) powered by reactive energy from the electrical network and capable of supporting two different voltages; an optocoupler-activated thyristor (4) from 100 V to 250 V that handles the electrical load; an input terminal block (5) and an output terminal block (6); a thermal safety fuse (10); a group of capacitors (7); a status indicator light (8); and a zero-crossing chip (9).

Most of the components on the electronic board (11) are secured by welding to its top side, and the minority of them are also secured by welding to its bottom side. Once the components are welded to the electronic board (11), both the board and the components undergo an anti-moisture and anti-corrosion coating treatment using products known in the market designed to protect electronic boards and their components.

Secondly, according to the preferred embodiment illustrated in the referenced figures, the switch module features a casing (17) in which the electronic board (11) with its components is installed. The casing (17) consists of a hollow rectangular prism open on one of its faces. Each of its two side faces has a lateral opening (19) from the inside to the outside on its surface, as well as a slot (18) of similar length and parallel to the inner bottom edge of each of them, where each of the two side edges of the electronic board (11) without components is inserted by pressure. The casing (17) also has two female-type cavities (20) near the side edges of the open face of the casing (17). Additionally, the casing (17) has two openings (22) on its top face.

Thirdly, the switch module features a casing (16) cover (17) made preferably of a plastic material, where the cover (16) consists of an opening from the inside to the outside on its surface, in which a piece (15) of plastic material suitable for allowing only IR spectrum light from the switch module to pass through is secured. The piece (15) of plastic material is attached to the casing cover (16), and this, in turn, is attached to the casing (17), using adhesive glue in both joints.

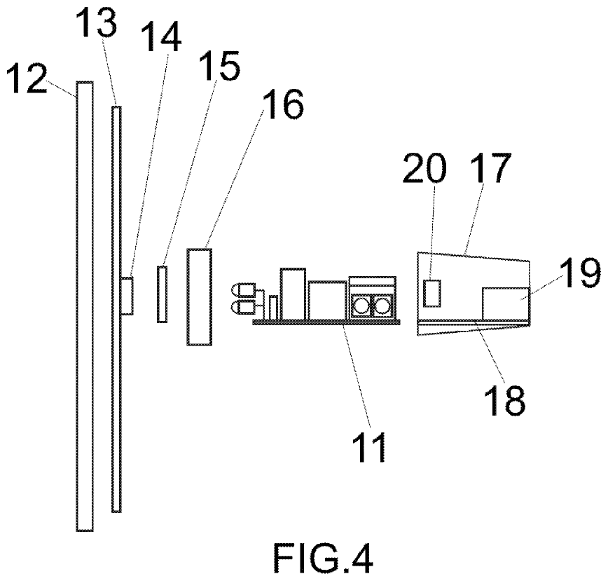

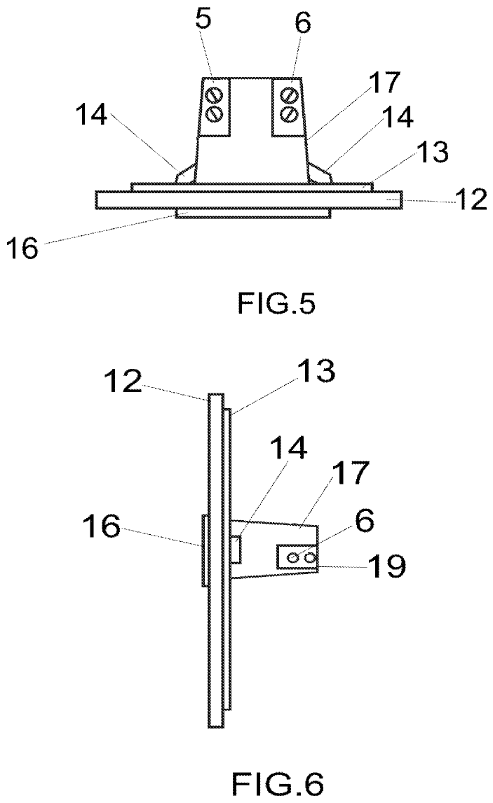

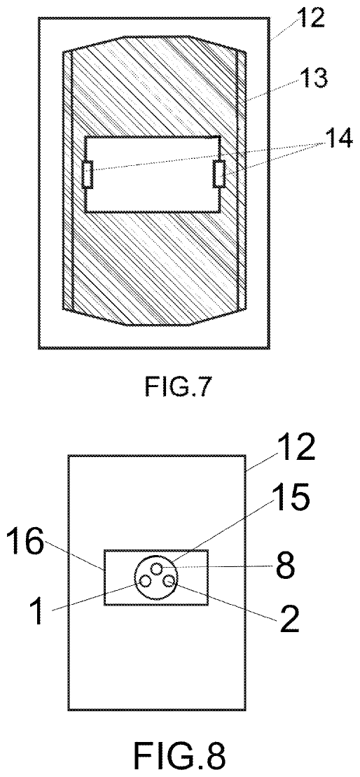

As seen in FIGS. 4 to 7, in a preferred embodiment, the module is accompanied by a back cover (13) with an opening and male-type protrusions (14), which are not part of the module, these are inserted into the female-type cavities (20) of the casing (17), and serve to insert the proximity activation switch module through an infrared reflective sensor into the wall enclosure.

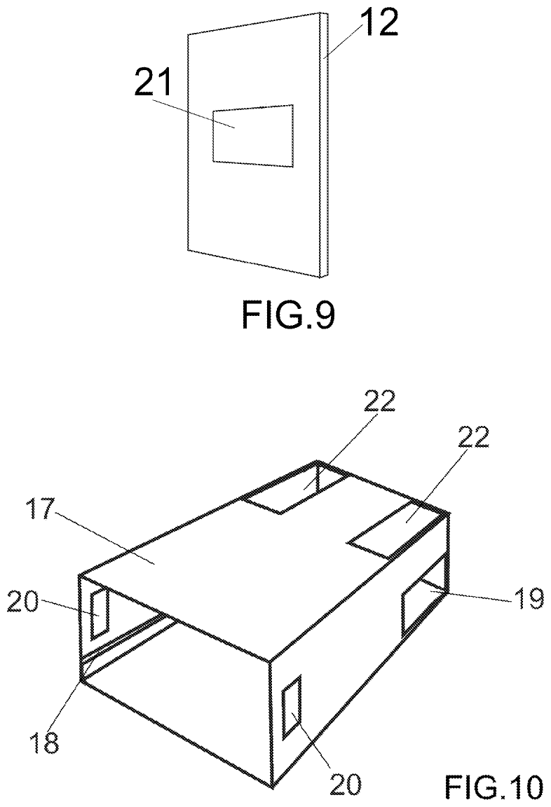

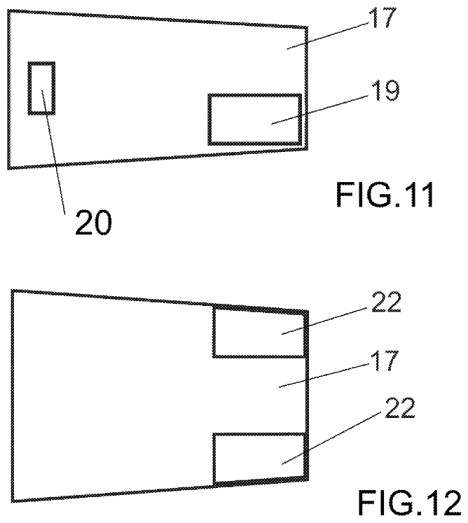

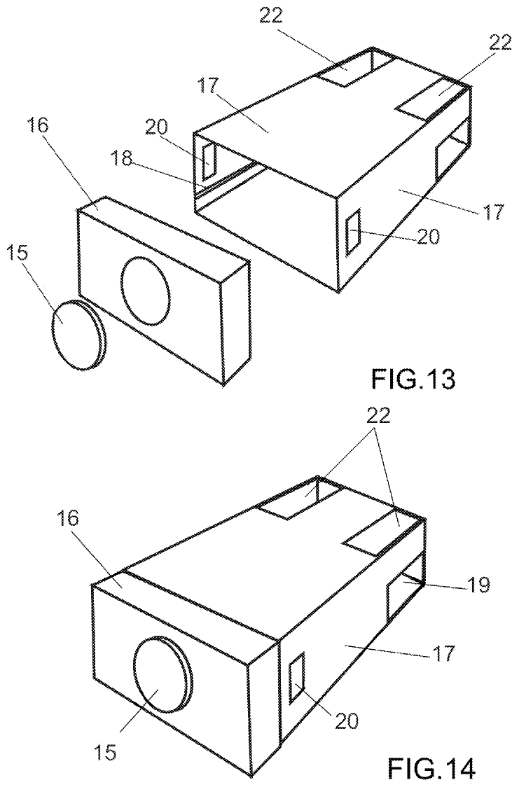

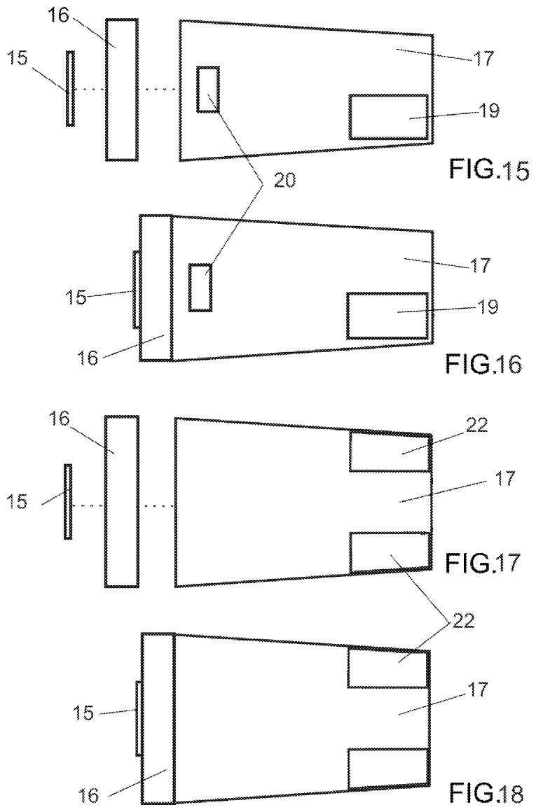

The switch module assembly is optionally complemented by a plate (12) with an opening (21), so that the plate is fixed to the wall or surface where the switch module of the invention is installed, as seen in FIGS. 4 to 9.

On the other hand, in order to expose the piece (15) of plastic material that only allows IR spectrum light from the switch module to pass through, the casing (16) cover (17) goes through the opening of the back cover (13) and the opening (21) of the plate (12).

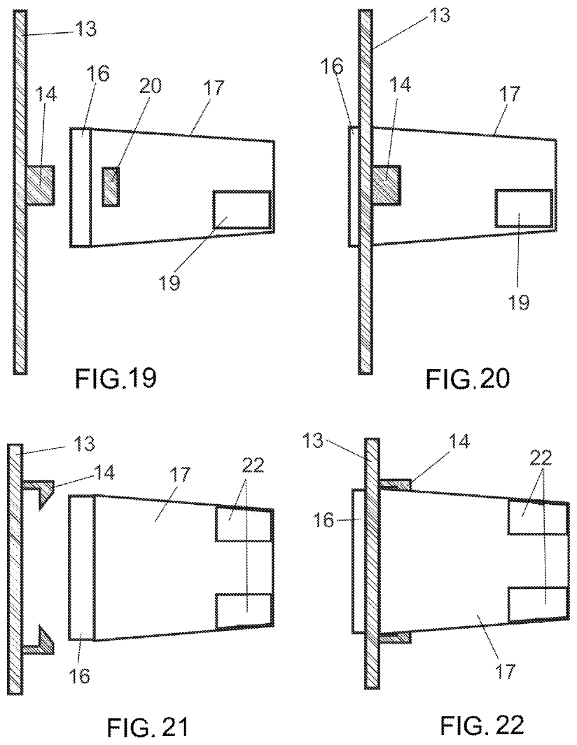

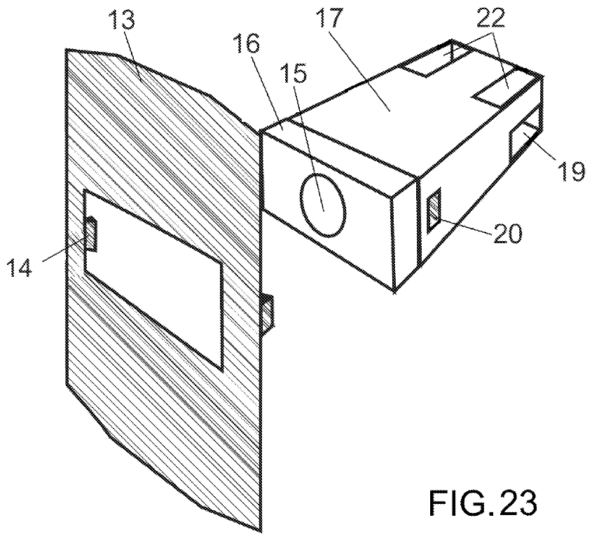

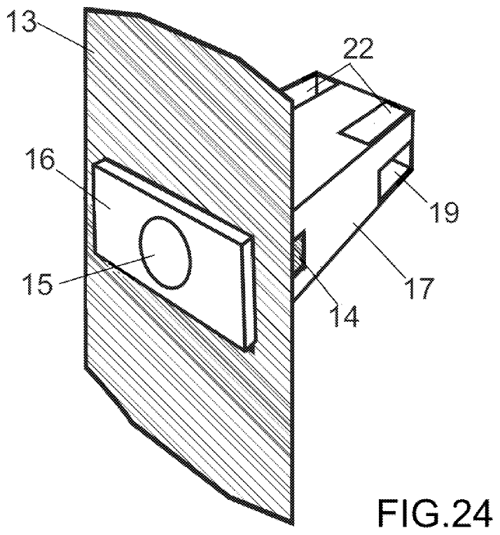

As detailed above, the male-type protrusions (14) of the back cover (13) are inserted into the female-type cavities (20) of the casing (17) before embedding the switch module in the wall enclosure, allowing the cover of the casing (16) with the piece (15) of plastic material suitable for allowing only IR spectrum light from the module to pass through, to go through the opening of the back cover (13), as seen in detail in FIGS. 19 to 24. Once the switch module is embedded in the wall, the plate (12) is placed on the back cover (13), allowing the casing (16) cover (17) with the piece (15) of plastic material to go through the opening (21) of the plate (12). The plate (12) is then secured to the wall by conventional means.

The proximity activation switch module using an infrared reflective sensor is connected to wiring before embedding it in the wall and operates without the need for adjustments. Before embedding the proximity activation switch module using an infrared reflective sensor, the input terminal block (5) and the output terminal block (6) are connected to the wiring.

Once installed and embedded in the wall, the switch module is activated when a body is brought close to the activation distance, approximately 7 cm (2.75 in), which activates both it's turning on and off. Thus, any volume or mass, such as the user's hand, brought to the activation distance causes it to turn on or off. To facilitate its use, the status indicator light (8) can be, for example, red when turned off and blue when turned on, so that the user can detect it in complete darkness.

Finally, it is worth noting that the proposed invention has industrial applications, as the components of the electronic board (11) are generic electronic components. The casing (17) is manufactured using plastic molding. The piece (15) of plastic material that only allows the passage of IR spectrum light from the module is manufactured, for example, by plastic injection molding or by die-cutting a plastic sheet.

1. A proximity switch module activated through an infrared reflective sensor, comprising:
an electronic board (11) including the following components:
an infrared reflective sensor including an infrared emitter (1) and an infrared receiver (2);
a capacitive power supply (3);
an optocoupler-activated thyristor (4);
a charge input terminal block (5), and a charge output terminal block (6);
a thermal safety fuse (10);
a plurality of capacitors (7);
a status indicator light (8);
a zero-crossing chip (9); and
a memory.
a casing (17) having a hollow rectangular prism shape, open on one of its faces, with two openings (22) on an upper face; with an opening (19) from an inside to an outside on a surface of each of two side faces; with a slot (18) inside each of one of the side faces that parallel to a lower edge of each of them; with a female-type cavity (20) next to each side edges of the open face of a rectangular prism; so that the electronic board (11) is inserted into the slots (18) of the side faces of the casing (17).
a casing (16) cover (17) having an opening from an inside to an outside on a surface;
a piece (15) of material capable of allowing only the infrared (IR) spectrum light from the proximity switch module to pass through.

2. The proximity switch module according to claim 1, wherein further comprising a back cover (13), an opening, and male-type protrusions (14) that are inserted into the female-type cavities (20) of the casing (17).

3. The proximity switch module according to claim 1, wherein the electronic board (11) and its components undergo an anti-moisture and anti-corrosion treatment.

4. The proximity switch module according to claim 1, wherein the components of the electronic board (11) are connected to the electronic board by welding.

5. The proximity switch module according to claim 1, wherein the piece of material (15) is joined to the casing (16) covering (17) by an adhesive glue, wherein the casing (16) covering (17) is joined to the casing (17) by an adhesive glue.
